(19) United States
(12) Patent Application Publication
(10) Pub. No.: US 2010/0178136 A1
(43) Pub. Date: Jul. 15, 2010

(54) SUBSTRATE TRANSFER ROBOT AND VACUUM PROCESSING APPARATUS

(75) Inventor: Kenji AGO, Chigasaki-shi (JP)

Correspondence Address: KRATZ, QUINTOS & HANSON, LLP, 1420 K Street, N.W., 4th Floor, WASHINGTON, DC, 20005, US

(73) Assignee: ULVAC, INC., Chigasaki-shi (JP)

(21) Appl. No.: 12/717,331

(22) Filed: Mar. 4, 2010

Related U.S. Application Data
(63) Continuation of application No. PCT/JP08/64008, filed on Aug. 5, 2008.

(30) Foreign Application Priority Data
Sep. 10, 2007 (JP) 2007-233543

(51) Int. Cl. B25J 18/04; B65G 49/07; H01L 21/68

(52) U.S. Cl. 414/217; 74/490.01

(57) ABSTRACT

Substrates are delivered in a short time among various processing chambers having various mounting positions. When first to fourth drive shafts rotate in a state such that an A-side rotary member and a B-side rotary member are stationary, first to fourth mounting portions linearly move on extension lines on respective ones of the sides thereof. When the first drive shaft and the A-side rotary member, the second drive shaft and the B-side rotary member, the third drive shaft and the A-side rotary member, and the fourth drive shaft and the B-side rotary member rotate by the same angle in the same direction, the first to fourth mounting portions are rotationally moved. When the linear motion is combined with the rotational motion, the first to fourth mounting portions can be moved to desired positions.

This application is a continuation of International Application No. PCT/JP2008/064008 filed Aug. 5, 2008, which claims priority to Japan Patent Document No. 2007-233543, filed on Sep. 10, 2007. The entire disclosures of the prior applications are herein incorporated by reference in their entireties.

### BACKGROUND

The present invention generally relates to a technical field of a substrate transfer robot. More particularly, the invention relates to a substrate transfer robot which can transfer a number of substrates.

Substrate transfer robots for carrying substrates out of and into processing chambers, which perform various processing treatments, have been previously used in semiconductor producing apparatuses.

For example, in a substrate transfer robot described in JPA 2006-13371, two arm portions are fitted to different drive shafts, respectively, so that they may move independently through expansion and contraction by rotation of the respective drive shafts. Furthermore, two arm portions are fitted to the same rotary shaft so that they may rotationally move together with the rotary shaft when the rotary shaft rotates.

In such substrate transfer robots, the two arm portions are effectively moved by three shafts; and a plurality of the substrates can be transferred by a simple construction.

However, since the two arm portions are fixed to the same arm rotary shaft in the above construction, an angle between the arm portions is fixed, so that the distance between the substrates mounted on the two arm portions cannot be changed.

In the case where the mounting positions inside the processing chamber differ from the distance between the substrates arranged on the substrate transfer robot, the substrates can only be transferred one by one when the substrate transfer robot carries the substrate out of and into the processing chamber. Such transfer increases the transfer time and decreases production effect.

The present invention has been made to solve the problems of such a conventional art technique, and the invention provides a substrate transfer robot which can deliver plural substrates in a short time by a smaller number of shafts.

### SUMMARY OF THE INVENTION

In order to solve the above-mentioned problems, the present invention is directed to a substrate transfer robot including first to fourth drive shafts, an A-type rotary member and a B-type rotary member each having an identical main rotary axis as central axes thereof and arranged to rotate around the main rotary axis, first to fourth arm portions to rotate around the main rotary axis, first to fourth mounting portions provided at the first to fourth arm portions and adapted to move linearly through expansion and contraction of the first to fourth arm portions, first and third auxiliary rotary axes and second and fourth auxiliary rotary axes which are arranged in positions spaced away from the main rotary axes, the first and third auxiliary rotary axes being rotationally moved around the main rotary axis by rotation of the A-type rotary member, and the second and fourth auxiliary rotary axes being rotationally moved around the main rotary axis by rotation of the B-type rotary member, first to fourth main drive arms, first to fourth auxiliary drive arms, and first to fourth main drive arms which are provided in the first to fourth arm portions, respectively, the first to fourth main drive arms being fixed to the first to fourth drive shafts provided in the first to fourth arm portions, respectively. The first and third auxiliary drive arms are arranged to be rotatable around the first and third auxiliary rotary axes, respectively; the second and fourth auxiliary drive arms are rotatably arranged around the second and fourth auxiliary rotary axes; and the first to fourth mounting portions are fitted to the first to fourth main drive arms via the first to fourth main driven arms, respectively. The first to fourth mounting portions are configured to move linearly through rotation of the first to fourth drive shafts around the main rotary axis, respectively, wherein the first to fourth main drive arms are connected to the first to fourth auxiliary drive arms via restraint members, respectively; and rotate following rotations of the first to fourth rotary shafts, respectively; and the first to fourth mounting portions are configured to rotationally move around the main rotary axis.

Further, the present invention is directed to the substrate transfer robot wherein the first main drive arm and the first auxiliary drive arm are arranged in parallel; the second main drive arm and the second auxiliary drive arm are arranged in parallel; the third main drive arm and the third auxiliary drive arm are arranged in parallel; the fourth main drive arm and the fourth auxiliary drive arm are arranged in parallel; tips of the first to fourth main drive arms and tips of the first to fourth auxiliary drive arms are rotatably fitted to the first to fourth restraint members, respectively; a first auxiliary driven arm is arranged in parallel to the first main driven arm; a second auxiliary driven arm is arranged in parallel to the second main driven arm; a third auxiliary driven arm is arranged in parallel to the third main driven arm; a fourth auxiliary driven arm is arranged in parallel to the fourth main driven arm; and base portions of the first to fourth main driven arms and base portions of the first to fourth auxiliary driven arms are rotatably fitted to the first to fourth restraint members, and tips of the first to fourth main driven arms and tips of the first to the fourth auxiliary driven arms are rotatably fitted to the first to fourth mounting portions.

Furthermore, the present invention is directed to the substrate transfer robot wherein the first to fourth main drive arms are arranged at different heights, respectively; the first to fourth main driven arms are arranged at different heights; the first to fourth mounting portions are arranged at different heights; and first to fourth mounting portions are configured to be rotatable around the main rotary axis without colliding with each other.

In addition, the present invention is directed to the substrate transfer robot wherein the first auxiliary rotary axis and the third auxiliary rotary axis are arranged at positions where they are spaced apart from each other; and the second auxiliary rotary axis and the fourth auxiliary rotary axis are arranged at positions where they are spaced apart from each other.

Still further, the present invention is directed to the substrate transfer robot wherein the first auxiliary rotary axis and the third auxiliary rotary axis are arranged in a coincident position, and the second auxiliary rotary axis and the fourth auxiliary rotary axis are arranged in a coincident position.

Still further, the present invention is directed to a vacuum processing apparatus including a transfer chamber which can be vacuum evacuated, and a processing chamber which is connected to the transfer chamber and in which an object to be processed is processed in a vacuum ambience, wherein the substrate transfer robot is arranged in the transfer chamber.

Since the distance between the first and third substrates and the distance between the second and fourth substrates as mounted on the substrate transfer robot can be changed, the substrates can be delivered among the various processing chambers at various mounting positions in a short time.

### BRIEF DESCRIPTION OF THE DRAWINGS

FIG. 1 is a plan view for schematically illustrating a vacuum processing apparatus according to the present invention.

FIG. 2 is a plan view of a substrate transfer robot of one embodiment of the present invention.

FIG. 3 is a side view of the substrate transfer robot of the one embodiment of the present invention.

FIG. 4 is a plan view for illustrating first and second arm portions.

FIG. 5 is a plan view for illustrating third and fourth arm portions.

FIG. 6 is a schematic view for illustrating a connected state of respective members of first to fourth arm portions.

### DETAILED DESCRIPTION OF THE INVENTION

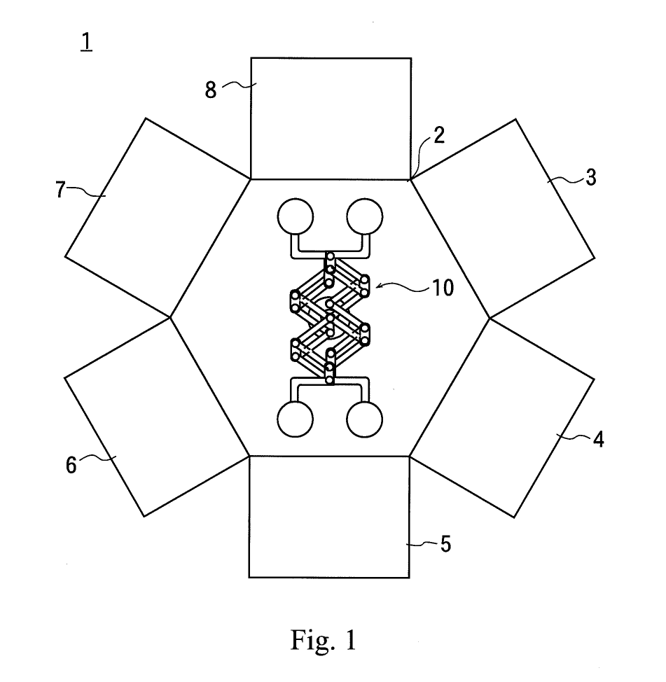

FIG. 1 is a schematic plan view of a vacuum processing apparatus 1 according to the present invention. This vacuum processing apparatus 1 includes a transfer chamber 2, one to plural processing chambers 3 to 8 connected to the transfer chamber 2, and a transfer robot 10 disposed inside the transfer chamber 2.

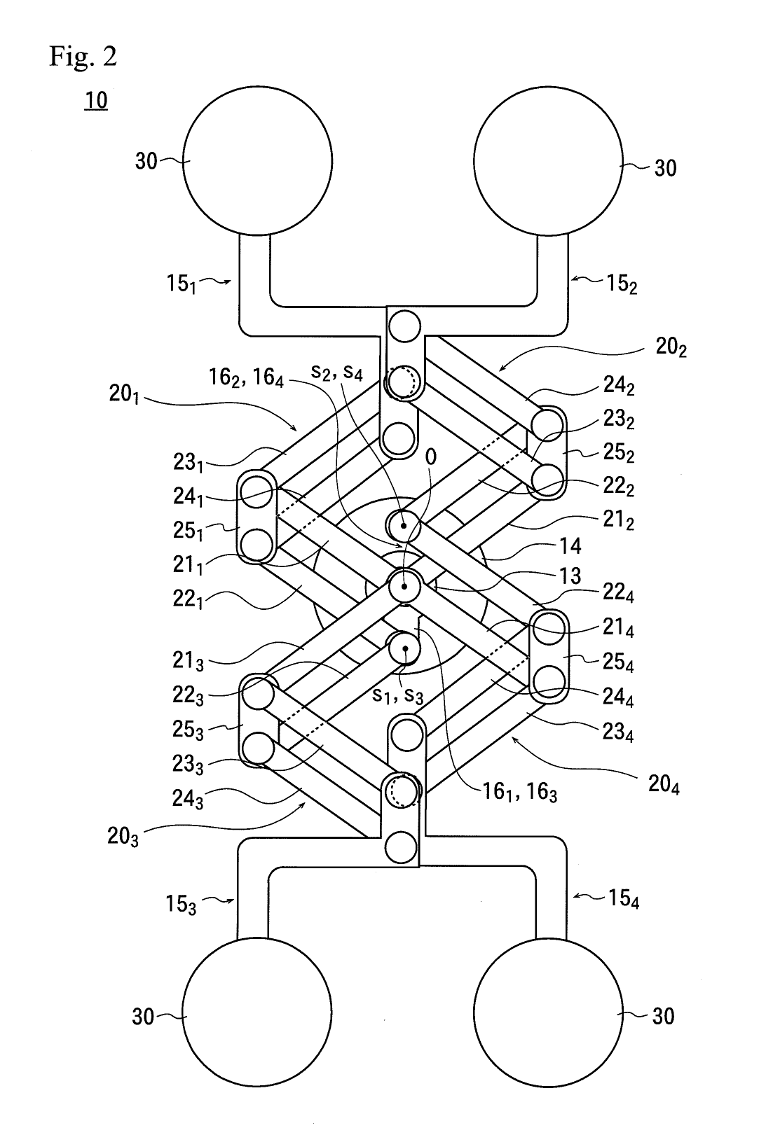

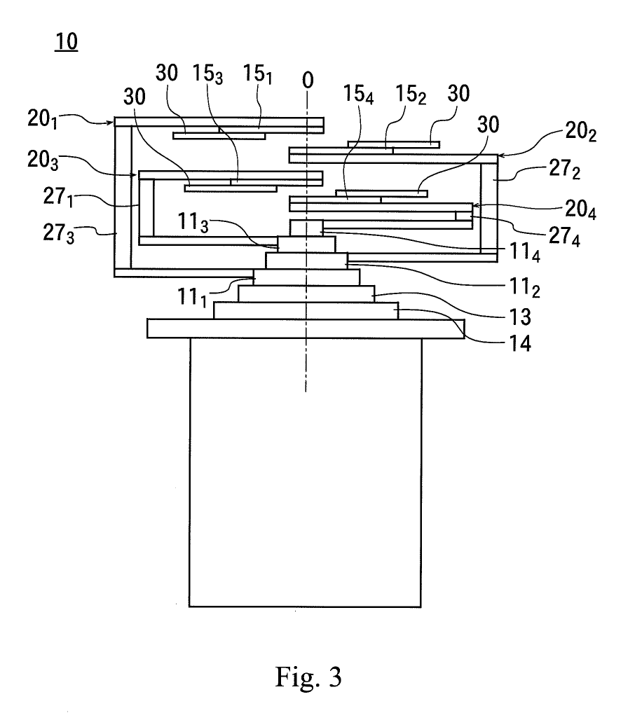

FIG. 2 is a plan view of a substrate transfer robot 10 of one embodiment of the present invention, and FIG. 3 is a side view thereof.

This substrate transfer robot 10 includes first to fourth drive shafts 11₁ to 11₄, an A-side rotary member 13, and a B-side rotary member 14.

The first to fourth drive shafts 11₁ to 11₄, the A-side rotary member 13, and the B-side rotary member 14 are vertically and coaxially arranged, so that they can each independently rotate around the identical main rotary axis O, which is the center axis of each shaft.

The substrate transfer robot 10 includes first to fourth arm portions 20₁ to 20₄ and first to fourth mounting portions 15₁ to 15₄.

The first to fourth arm portions 20₁ to 20₄ includes first to fourth main drive arms 21₁ to 21₄, first to fourth auxiliary drive arms 22₁ to 22₄, first to fourth main driven arms 23₁ to 23₄, first to fourth auxiliary driven arms 24₁ to 24₄, and first to fourth plate shaped restraint members 25₁ to 25₄, respectively.

Base portions of the first to fourth main drive arms 21₁ to 21₄ are fixed to first to fourth drive shafts 11₁ to 11₄, respectively, so that when the first to the fourth drive shafts 11₁ to 11₄ rotate, the first to fourth main drive arms 21₁ to 21₄ rotate within horizontal planes by the same angle and in the same direction as the rotating angle of the first to fourth drive shafts 11₁ to 11₄.

First and third auxiliary rotary axes s₁, s₃ are provided at a position of the A-side rotary member 13 spaced apart from the main rotary axis 0, while second and fourth auxiliary rotary axes s₂, s₄ are provided at a position of the B-side rotary member 14 spaced apart from the main rotary axis 0. The main rotary axis 0 and the first to fourth auxiliary rotary axes s₁ to s₄ are set vertical.

Assuming that a portion of the A-side rotary member 13 between the main rotary axis 0 and the first and third auxiliary rotary axes s₁, s₃ are first and third rotary arms 16₁, 16₃, respectively, and that a portion of the B-side rotary member 14 between the main rotary axis 0 and the second and fourth auxiliary rotary axes s₂, s₄ are second and fourth rotary arms 16₂, 16₄, respectively, base portions of first to fourth auxiliary drive arms 22₁ to 22₄ are fitted to tip portions of the first to fourth rotary arms 16₁ to 16₄ such that they are rotatable within horizontal planes around the first to fourth auxiliary rotary axes s₁ to s₄, respectively.

In this embodiment, the first and third auxiliary rotary axes s₁, s₃ are coincident with each other; and the second and forth auxiliary rotary axes s₂, s₄ are coincident with each other. The first and third rotary arms 16₁, 16₃ and the second and fourth rotary arms 16₂, 16₄ are constituted by the identical portions of the A-side and B-side rotary members 13, 14, respectively. The first and third auxiliary drive arms 22₁, 22₃ rotate around the identical rotary axis (first and third auxiliary rotary axes s₁, s₃), respectively, and the second and fourth auxiliary drive arms 22₂, 22₄ rotate around the identical rotary axis (second and fourth auxiliary rotary axes s₂, s₄), respectively.

Consequently, it may be that the first and third auxiliary rotary axes s₁, s₃ are spaced apart and that the second and fourth rotary axes s₂, s₄ are spaced apart. For example, it may be that the first and third auxiliary rotary axes s₁, s₃ are arranged at positions spaced apart by 180 degrees around the main rotary axis 0 and that the second and fourth auxiliary rotary axes s₂, s₄ are arranged at positions spaced apart by 180 degrees around the main rotary axis.

A first restraint member 25₁ is provided at a tip end portion of the first main drive arm 21₁ and tip end portion of the first auxiliary drive arm 22₁ such that the first main drive arm 21₁ and the first auxiliary drive arm 22₁ are rotatable.

The base portion of the first main driven arm 23₁ and the base portion of the first auxiliary arm 24₁ are fitted to the first restraint member 25₁ rotatably within horizontal planes. Meanwhile, a first mounting portion 15₁ is fitted to a tip portion of the first main driven arm 23₁ and a tip portion of the first auxiliary driven arm 24₁ such that the first main driven arm 23₁ and the first auxiliary driven arm 24₁ are rotatable within horizontal planes.

In the same manner, second and fourth restraint members 25₂, 25₄ are fitted to the tips of second and fourth main drive arms 21₂, 21₄ and tips of the second and fourth auxiliary drive arms 22₂, 22₄, respectively, such that the second and fourth main drive arms 21₂, 21₄ and the second and fourth auxiliary drive arms 22₂, 22₄ are rotatable within horizontal planes.

Base portions of the second and fourth main driven arms 23₂, 23₄ and base portions of the second and forth auxiliary driven arms 24₂, 24₄ are fitted to the second and fourth restraint members 25₂, 25₄, respectively, such that the second and fourth main driven arms 23₂, 23₄ are rotatable within horizontal planes. Further, the second and fourth mounting portions 15₂, 15₄ are fitted to tip portions of the second and fourth main driven arms 23₂, 23₄ and to tip portions of the second and fourth auxiliary driven arms 24₂, 24₄, respectively, such that the second and fourth mounting portions 15₂, 15₄ are rotatable within horizontal planes.

In this embodiment, the base portions of the first to fourth main driven arms 23₁ to 23₄ are connected to the same places on the first to fourth restraint members 25₁ to 25₄ at the positions where the tip portions of for the first to fourth main drive arms 21₁ to 21₄ are connected. Further, the base portions of the first to fourth auxiliary driven arms 24₁ to 24₄ are connected to the same places on the first to fourth restraint members 25₁ to 25₄ at the positions where the tip portions of the first to fourth auxiliary drive arms 22₁ to 22₄ are connected. The first to fourth main drive arms 21₁ to 21₄ and the first to fourth main driven arms 23₁ to 23₄ are rotatable around the same rotary axes respectively passing through their central axes. Also, the first to fourth auxiliary drive arms 22₁ to 22₄ and the first to fourth auxiliary driven arms 24₁ to 24₄ are rotatable around the same rotary axes respectively passing through their central axes.

The rotary center of each of the drive and driven arms 21₁ to 21₄, 22₁ to 22₄, 23₁ to 23₄, and 24₁ to 24₄ is set perpendicular and in parallel to the main rotary axis O and the first to fourth auxiliary rotary axes s₁ to s₄. Each of the arms 16₁ to 16₄, 21₁ to 21₄, 22₁ to 22₄, 23₁ to 23₄ and 24₁ to 24₄ and the first to fourth mounting portions 15₁ to 15₄ are configured such that when each of the arms 16₁ to 16₄, 21₁ to 21₄, 22₁ to 22₄, 23₁ to 23₄, and 24₁ to 24₄ rotates, the first to fourth mounting portions can move within horizontal planes. When substrates 30 are placed on tip portions of below-discussed first to fourth support arms 18₁ to 18₄ provided in the first to fourth mounting portions 15₁ to 15₄, respectively, the substrates 30 can be transported.

In particular, when the first drive shaft 11₁ and the A-side rotary member 13 rotate by the same angle in the same direction, the first auxiliary rotary axis s₁, each of the arms 21₁, 22₁, 23₁, 24₁ in the first arm 20₁, the first restraint member 25₁ and the first mounting portion 15₁ rotate together such that they are stationary relative to each other, while the substrate 30 rotationally moves around the main rotary axis O.

However, since the third auxiliary rotary axis s₃ provided on the A-side rotary member 13 also rotates by the same angle in the same direction, the substrate 30 on the third arm portion 20₃ also moves, so that the first mounting portion 15₁ cannot be moved independently from the substrate 30 on the third mounting portion 15₃. The second mounting portion 15₂ and the fourth mounting portion 15₄ have the same relation, so that they cannot be moved independently.

On the other hand, since the A-side rotary member 13 and the B-side rotary member 14 can rotate independent from each other, the first mounting portion 15₁ and the second mounting member 15₂ can be moved independently. The third mounting portion 15₃ and the fourth mounting portion 15₄ have the same relation as mentioned above.

In the present invention, when the first and second arm portions 20₁, 20₂ are taken as one set and the third and fourth arm portions 20₃, 20₄ are taken as the other set, the distances and the relative positions between the first mounting portion 15₁ and the second mounting portion 15₂ and between the third mounting portion 15₃ and the fourth mounting portion 15₄ can be changed by varying the angle between the A-side rotary member 13 and the B-side rotary member 14.

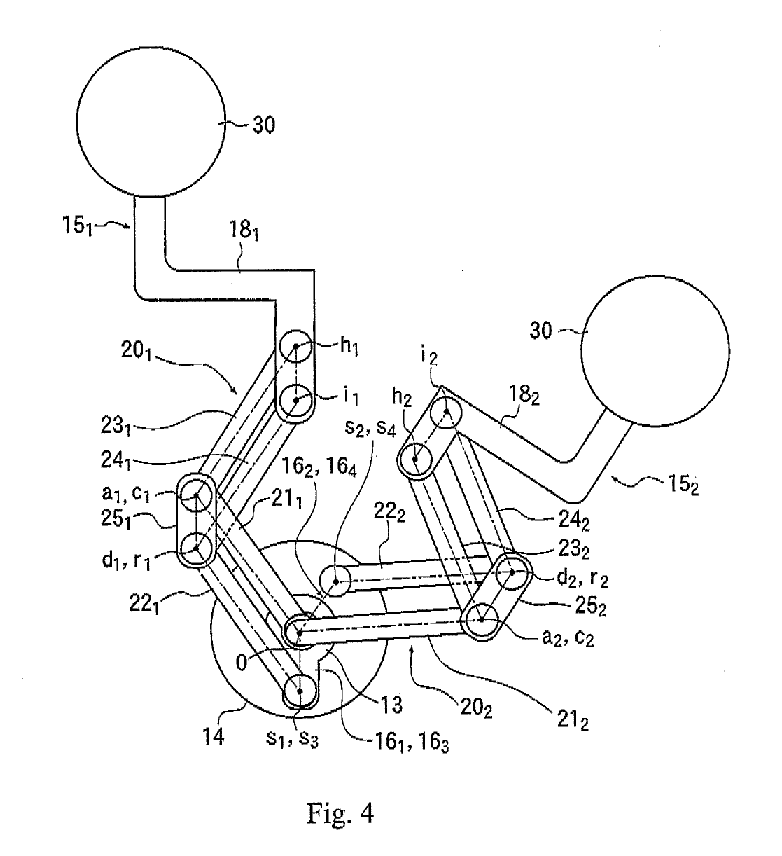

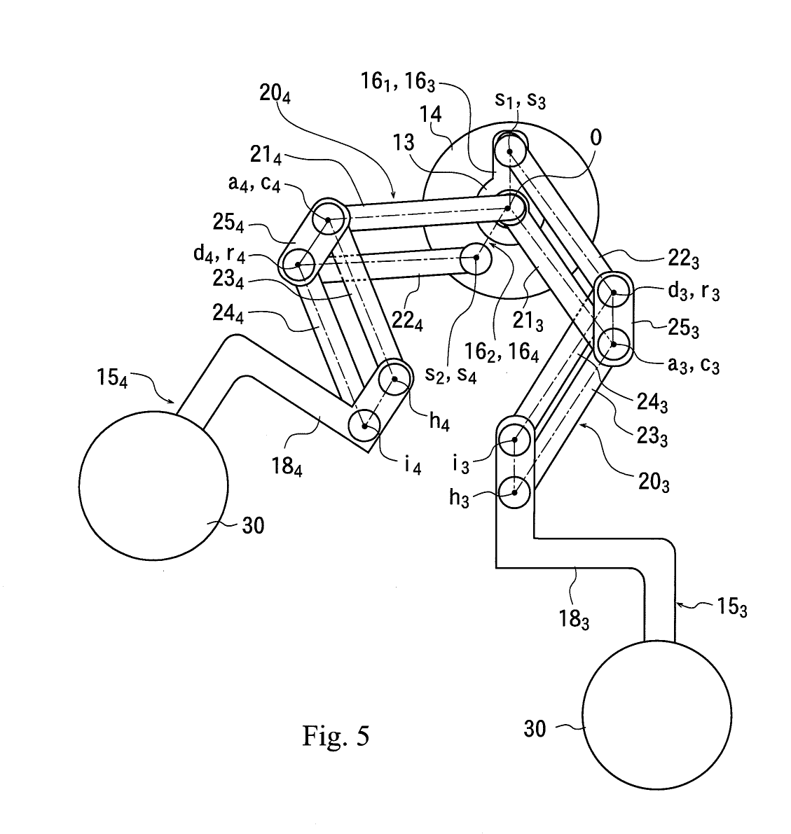

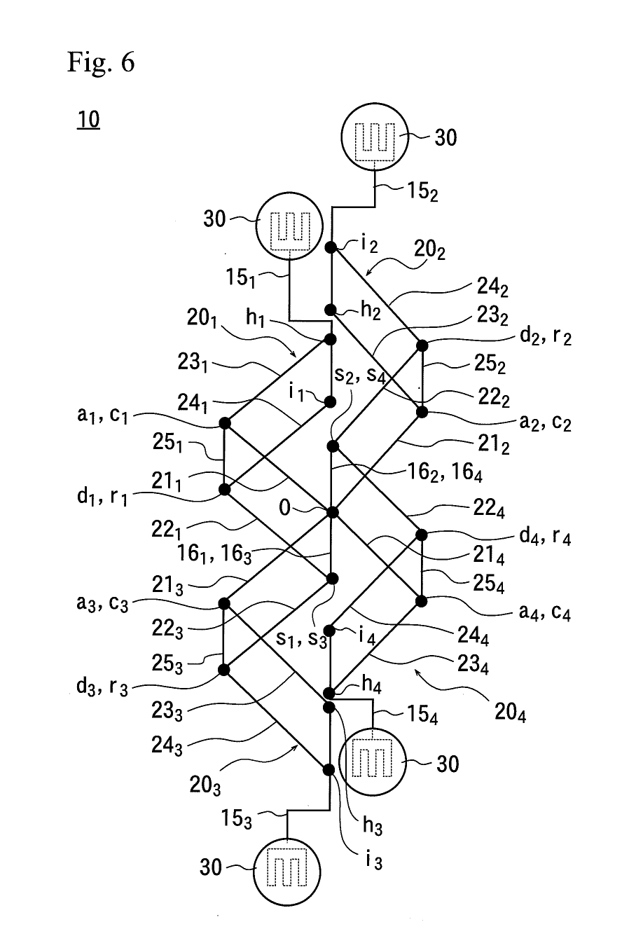

FIG. 4 is a plan view for illustrating the first and second arm portions 20₁, 20₂, and FIG. 5 is a plan view for illustrating the third and fourth arm portions 20₃, 20₄. FIG. 6 is a schematic view for illustrating the connected state of the respective members.

In FIG. 4 to FIG. 6, reference signs are shown in order to designate distances between the rotary axes and distances between the main rotary axis O and the rotary axes.

The reference signs a₁ to a₄ are rotary axes of the first to fourth main drive arms 21₁ to 21₄, and the first to fourth restraint members 25₁ to 25₄ rotate around the rotary axes a₁ to a₄. Reference signs r₁ to r₄ are rotary axes of the first to fourth auxiliary drive arms 22₁ to 22₄, respectively; and the first to fourth restraint members 25₁ to 25₄ rotate around the rotary axes r₁ to r₄, respectively.

Each of the rotary axes 0 and s₁ to s₄ and each of the rotary axes a₁ to a₄ and r₁ to r₄ are vertically set.

Regarding the first to fourth arm portions 20₁ to 20₄, distances between the axes are set such that quadrangles Os₁r₁a₁, Os₂r₂a₂, Os₃r₃a₃, Os₄r₄a₄ formed by horizontally connecting the main rotary axis O, the first to fourth auxiliary rotary axes s₁ to s₄, the rotary axis a₁ to a₄ and r₁ to r₄ are parallelograms (including square, rectangle and rhombic shapes).

Furthermore, in this embodiment, distances Oa₁ to Oa₄ between the main rotary axis O and the rotary axes a₁ to a₄ of the first to fourth main drive arms 21₁ to 21₄ are set as the same distance Oa. Therefore, distances s₁r₁ to s₄r₄ between the first to fourth auxiliary rotary axes s₁ to s₄ and the rotary axes r₁ to r₄ of the first to fourth auxiliary drive arms 22₁ to 22₄, which are in parallel to the distances Oa₁ to Oa₄, are set at the same distance sr as the distance Oa between the main rotary axis O and the rotary axes a₁ to a₄ of the first to fourth main drive arms 21₁ to 21₄ (Oa=sr).

Similarly, distances Os₁ to Os₄ between the main rotary axis O and the first to fourth auxiliary rotary axes s₁ to s₄ are set as the same distance Os regarding the distances between the first to fourth main drive arms 21₁ to 21₄ and the first to fourth auxiliary drive arms 22₁ to 22₄. (In this embodiment, as discussed above, the first and third auxiliary rotary axes s₁, s₃ are coincident, and the second and fourth auxiliary rotary axes s₂, s₄ are coincident). Therefore, the distances a₁r₁ to a₄r₄ between the rotary axes a₁ to a₄ of the first to fourth main drive arms 21₁ to 21₄ and the rotary axes r₁ to r₄ of the first to fourth auxiliary drive arms 22₁ to 22₄ are set to the same distance ar as the distance Os (Os=ar).

Next, signs c₁ to c₄ in FIGS. 4 to 6 show rotary axes of the first to fourth main driven arms 23₁ to 23₄ to the first to fourth restraint members 25₁ to 25₄, and signs d₁ to d₄ show rotary axes of the first to fourth auxiliary driven arms 24₁ to 24₄ for the first to fourth restraint members 25₁ to 25₄. (As discussed above, in this embodiment, the rotary axes c₁ to c₄ of the first to fourth main driven arms 23₁ to 23₄ are coincident with the rotary axes a₁ to a₄ of the first to fourth main drive arms 21₁ to 21₄; and the rotary axes d₁ to d₄ of the first to fourth auxiliary driven arms 24₁ to 24₄ are coincident with the rotary axes r₁ to r₄ of the first to fourth auxiliary drive arms 22₁ to 22₄).

In addition, signs h₁ to h₄ show rotary axes of the first to fourth main driven arms 23₁ to 23₄ for the first to fourth mounting portions 15₁ to 15₄; and signs iₜ to i₄ show rotary axes of the first to fourth auxiliary driven arms 24₁ to 24₄ for the first to fourth mounting portions 15₁ to 15₄.

Each of the rotary axes c₁ to c₄, d₁ to d₄, h₁ to h₄ and iₜ to i₄ are vertically disposed, and the distances between the rotary axes are set such that quadrangles c₁h₁i₁d₁, c₂h₂i₂d₂, c₃h₃i₃d₃, c₄h₄i₄d₄ formed by horizontally connecting the rotary axes c₁ to c₄, h₁ to h₄ at the both ends of the first to fourth main driven arms 23₁ to 23₄ with the rotary axes d₁ to d₄, to i₄ at the both ends of the first to fourth auxiliary driven arms 24₁ to 24₄ are parallelograms (including squares, rectangles or rhombic shapes).

Moreover, in this embodiment, the distances c₁h₁ to c₄h₄ between the rotary axes c₁ to c₄ and h₁ to h₄ at the both ends of the first to fourth main driven arms 23₁ to 23₄ are set to the same distance ch, so that the distances d₁i₁ to d₄i₄ between the rotary axes d₁ to d₄ and i₁ to i₄ at the both ends of the first to fourth auxiliary rotary driven arms 24₁ to 24₄ are set to the same distance di as the distance ch (ch=di).

Similarly, distances c₁d₁ to c₄d₄ between the rotary axes c₁ to c₄ and d₁ to d₄ on the first to fourth restraint members 25₁ to 25₄ are set to the same distance cd regarding the first to fourth restraint members 25₁ to 25₄ and the first to fourth mounting portions 15₁ to 15₄. Therefore, distances h₁i₁ to h₄i₄ between the rotary axes h₁ to h₄ and iₜ to i₄ on the first to fourth mounting portions 15₁ to 15₄ are set to the same distance hi as the distance cd (cd=hi).

In the parallelogram Os₁r₁a₁, Os₂r₂a₂, Os₃r₃a₃, Os₄r₄a₄ containing the first to fourth main drive arms 21₁ to 21₄, sides Os₁ to Os₄ which are the first to fourth rotary arms 16₁ to 16₄, are parallel to respective ones of the sides a₁r₁ to a₄r₄ on the first to fourth restraint members 251 to 254, and one sides c₁d₁ to c₄d₄ on the first to fourth restraint members 25₁ to 25₄ in the quadrangles c₁h₁i₁d₁, c₂h₂i₂d₂, c₃h₃i₃d₃, c₄h₄i₄d₄ including the first to fourth main driven arms 23₁ to 23₄ are set in parallel to the one sides a₁r₁ to a₄r₄ (In this, the lengths of the sides c₁d₁ to c₄d₄ are coincident with those a₁r₁ to a₄r₄, and the distance cd=distance ar).

When the first to fourth drive shafts 11₁ to 11₄ rotate in a state such that the A-side rotary member 13 and the B-side rotary member 14 are stationary; and therefore, the first to fourth drive arms 16₁ to 16₄ are stationary, and the quadrangles of the first to fourth arm portions 20₁ to 20₄ are deformed.

The lengths of the mutually parallel four sides: Os₁ to Os₄, a₁r₁ to a₄r₄, c₁d₁ to c₄d₄, h₁i₁ to h₄i₄ are equal in two parallelograms of the respective arm portions 20₁ to 20₄: Os₁r₁a₁, Os₂r₂a₂, Os₃r₃a₃, Os₄r₄a₄, C₁h₁i₁d₁, C₂h₂i₂d₂, C₃h₃i₃d₃, C₄h₄i₄d₄. Therefore, when the lengths of the other four sides: Oa₁ to Oa₄, s₁r₁ to s₄r₄, c₁h₁ to c₄h₄, d₁i₁ to d₄i₄ are equal, respective ones of the sides horizontally connecting the rotary axes on the first to fourth mounting portions 15₁ to 15₄ move linearly on extension lines of the sides.

Since the first to fourth mounting portions 15₁ to 15₄ are fixed to the linearly moving sides, when the first to fourth drive shafts 11₁ to 11₄ rotate in a state such that the A-side rotary member 13 and the B-side rotary member 14 are stationary, the first to fourth mounting portions 15₁ to 15₄ move linearly on the extension lines of the sides.

On the other hand, when the first drive shaft 11₁ and the A-side rotary member 13 rotate by the same angle in the same direction, the first arm portion 20₁ and the first mounting portion 15₁ rotate around the main rotary axis O by the same angle in the same direction. Similarly, the second drive shaft 11₂ and the B-side rotary member 14, the third drive shaft 11₃ and the A-side rotary member 13, and the fourth drive shaft 11₄ and the B-side rotary member 14 rotate by the same angle in the same direction, the second to fourth arm portions 20₂ to 20₄ and the second to fourth mounting portions 15₂ to 15₄ rotate around the main rotary axis O by the same angle in the same direction, so that the first to fourth mounting portions 15₁ to 15₄ are rotationally moved.

Therefore, when the linear movement is combined with the rotary motion, the first to fourth mounting portions 15₁ to 15₄ can be moved to desired places.

More particularly, when the first and second arm portions 20₁, 20₂ are taken as one set and the third to fourth arm portions 20₃, 20₄ are taken as another set, the distances and the relative positions between the same set of the mounting portions 15₁ to 15₄ (i.e., between the first mounting portion 15₁ and the second mounting portion 15₂ or between the third mounting portion 15₃ and the fourth mounting portion 15₄) can be changed by varying the angle between the A-side rotary member 13 and the B-side rotary member 14. Therefore, if the same set of the mounting portions 15₁ to 15₄ is inserted in the same processing chamber 3 to 8, two substrates 30 can be moved in or out together.

When a vertically movable transfer mechanism is provided inside the processing chambers 3 to 8, at the time of carrying in, the substrates 30 placed on the tips of the first to fourth mounting portions 15₁ to 15₄ are positioned above the transfer mechanism, the substrates 30 on the first to fourth mounting portions 15₁ to 15₄ are moved onto the transfer mechanisms by raising it. At the time of carrying out, the tips of the first to fourth mounting portions 15₁ to 15₄ are inserted under the substrates 30 placed on the transfer mechanism, and the substrates 30 can be transferred onto the first to fourth mounting portions 15₁ to 15₄ by lowering the transfer mechanism.

Meanwhile, when the first to fourth drive shafts 11₁ to 11₄, the A-side rotary member 13 and the B-side rotary member 14 are configured to be vertically movable, at the time of the carrying in, the substrates 30 placed on the tips of the first to fourth mounting portions 15₁ to 15₄ are positioned above the transfer mechanism, and the substrates 30 on the first to fourth mounting portions 15₁ to 15₄ are transferred onto the transfer mechanism by lowering the first to fourth mounting portions 15₁ to 15₄. At the time of carrying out, the tips of the first to fourth mounting portions 15₁ to 15₄ are inserted under the substrates 30 placed on the transfer mechanism, and the substrates 30 can be transferred onto the mounting portions 15₁ to 15₄ by raising the first to fourth mounting portions 15₁ to 15₄.

The arms 16₁ to 16₄, 21₁ to 21₄, 22₁ to 22₄, 23₁ to 23₄, 24₁ to 24₄ are arranged at different heights, respectively; and the arms 16₁ to 16₄, 21₁ to 21₄, 22₁ to 22₄, 23₁ to 23₄, 24₁ to 24₄, which are at the heights different from those of the first to fourth restraint members 25₁ to 25₄ and the first to fourth mounting portions 15₁ to 15₄, are connected to the first to fourth restraint portions 25₁ to 25₄ or first to fourth mounting portions 15₁ to 15₄ by connecting pipes 27₁ to 27₄ arranged perpendicularly.

Since each of the arms 16₁ to 16₄, 21₁ to 21₄, 22₁ to 22₄, 23₁ to 23₄, 24₁ to 24₄ and each of the mounting portions 15₁ to 15₄ are different in height from each other, each of the arms 16₁ to 16₄, 21₁ to 21₄, 22₁ to 22₄, 23₁ to 23₄, 24₁ to 24₄ and each of the mounting portions 15₁ to 15₄ do not collide with each other when the first to fourth mounting portions 15₁ to 15₄ horizontally move.

Four sides: Os₁ to Os₄, a₁r₁ to a₄r₄, c₁d₁ to c₄d₄, h₁i₁ to h₄i₄ are equal in length among sides of two parallelograms Os₁r₁a₁, Os₂r₂a₂, Os₃r₃a₃, Os₄r₄a₄, c₁h₁i₁d₁, c₂h₂i₂d₂, c₃h₃₁₃d₃, c₄h₄i₄d₄ of each of the arms 20₁ to 20₄: (Os=ar=cd=hi), and respective ones of the sides (a₁rₛ to a₄r₄, c₁d₁ to c₄d₄) are common (other four sides: Oa₁ to Oa₄, s₁r₁ to s₄r₄, c₁h₁ to c₄h₄, d₁i₁ to d₄i₄ are equal in length (Oa=sr=ch=di)).

In this case, when the first and third auxiliary rotary axes s₁, s₃ are arranged on one side of the main rotary axis O and the second and fourth auxiliary rotary axes s₂, s₄ are arranged on the opposite side while the main rotary axis O is center, and the main rotary axis O and the first to fourth auxiliary rotary axis s₁ to s₄ are positioned within the same perpendicular plane, the rotary axes h₁ to h₄, i₁ to i₄ on the first to fourth mounting portions 15₁ to 15₄ are also positioned within that perpendicular plane.

The first and third restraint members 25₁, 25₃ are positioned on one side of that perpendicular plane, and the second and fourth restraint members 25₂, 25₄ are positioned on the opposite side. In the first to fourth mounting portions 15₁ to 15₄, there are provided first to fourth support arms 18₁ to 18₄ which extend on sides where the first to fourth restraint members 25₁ to 25₄ are arranged, and the substrates 30 can be arranged at the tips of the first to fourth support arms 18₁ to 18₄.

In a state such that the main rotary axis O and the first to fourth auxiliary rotary axes s₁ to s₄ are positioned within the same perpendicular plane, the substrates 30 placed on the first to fourth mounting portions 15₁ to 15₄ are positioned away from each other without crossing the perpendicular plane.

Furthermore, the first mounting portion 15₁ and the second mounting portion 15₂ are positioned on the same side of a plane which passes the main rotary axis O and is vertical to that perpendicular plane. When the first and second mounting portions 15₁, 15₂ move linearly by the same distance in the same direction, the first and second mounting portions 15₁, 15₂ are inserted into or removed from the same processing chamber 3 to 8.

Similarly, when the third auxiliary rotary axis s₃ and the fourth auxiliary rotary axis s₄ are positioned on the opposite side around the main rotary axis O, and the third auxiliary rotary axis s₃, the fourth auxiliary rotary axis s₄ and the main rotary axis O are included on the same plane, the third mounting portion 15₃ and the fourth mounting portion 15₄ are positioned on opposite sides of that plane, respectively, and on the same side of a plane including the main rotary axis O and being vertical to that plane.

In this embodiment, the first and third auxiliary rotary axes s₁, s₃ are coincident, and the second and fourth auxiliary rotary axes s₂, s₄ are also coincident. Meanwhile, the first and second mounting portions 15₁, 15₂ are positioned on a side opposite to the third and fourth mounting portions 15₃, 15₄ with respect to a plane, as a boundary, including the main rotary axis O and being vertical to the plane including the first and third auxiliary rotary axes s₁, s₃, the main rotary axis O, and the second and fourth auxiliary rotary axes s₂, s₄.

Therefore, when the first mounting portion 15₁ and the second mounting portion 15₂ or the third mounting portion 15₃ and the fourth mounting portion 15₄ are carried into a single processing chamber 3 to 8, two substrates 30 can be carried in or carried out of the processing chamber 3 to 8 by a single carrying operation.

The angle formed between the first auxiliary drive arm 22₁ and the third auxiliary drive arm 22₃ is set equal to the angle formed between the second auxiliary drive arm 22₂ and the fourth auxiliary drive arm 22₄, so that the angle formed between the first and second auxiliary drive arms 22₁, 22₂ is equal to the angle between the third and fourth auxiliary drive arms 22₃, 22₄.

Furthermore, in the above embodiment, the rotary axis 0 and the s₁ to s₄ are connected by the arms 16₁ to 16₄, 21₁ to 21₄, 22₁ to 22₄, 23₁ to 23₄, 24₁ to 24₄, respectively such that the distances may not be changed. Alternatively, they can be connected by gears instead of the arms. Further, rotary forces may be alternatively transmitted by belts.

In the above embodiment, explanation has been made of the substrate transfer robot 10 having the first to fourth arm portions 20₁ to 20₄ and the first to fourth mounting portions 15₁ to 15₄, but the substrate transfer robot of the present invention may be constructed of first and second arm portions 20₁, 20₂ and first and second mounting portions 15₁, 15₂ such that the auxiliary rotary axes are provided on separate rotary members (the A-side rotary member and the B-side rotary member) and without providing the third and fourth mounting portions 15₃, 15₄.

Furthermore, the substrate transfer robot may be constructed by the first and third arm portions 20₁, 20₃ having the auxiliary rotary axes in the same rotary member (the A-side rotary member or the B-side rotary member) and the first and third mounting portions 15₁, 15₃, without providing the second and forth mounting portions 15₂ or 15₄. In this case, the first and third auxiliary rotary axes s₁, s₃ may be arranged in places that spaced apart or in a coincident position.

What is claimed is:

1. A substrate transfer robot, comprising:
first to fourth drive shafts, an A-type rotary member and a B-type rotary member having an identical main rotary axis as central axes thereof and arranged to rotate around the main rotary axis;
first to fourth arm portions to rotate around the main rotary axis;
first to fourth mounting portions provided at the first to fourth arm portions and adapted to move linearly through expansion and contraction of the first to fourth arm portions;
first and third auxiliary rotary axes and second and fourth auxiliary rotary axes arranged in positions spaced apart from the main rotary axes, the first and third auxiliary rotary axes being rotationally moved around the main rotary axis by rotation of the A-type rotary member, and the second and fourth auxiliary rotary axes being rotationally moved around the main rotary axis by rotation of the B-type rotary member,
the first to fourth arm portions respectively including:
first to fourth main drive arms,
first to fourth auxiliary drive arms, and
first to fourth main drive arms,
wherein the first to fourth main drive arms are fixed to the first to fourth drive shafts, respectively, provided in the first to fourth arm portions, respectively,
wherein the first and third auxiliary drive arms are arranged to be rotatable around the first and third auxiliary rotary axes, respectively,
wherein the second and fourth auxiliary drive arms are rotatably arranged around the second and fourth auxiliary rotary axes, respectively,
wherein the first to fourth mounting portions are fitted to the first to fourth main drive arms via the first to fourth main driven arms, respectively,
wherein the first to fourth mounting portions are configured to move linearly through rotation of the first to fourth drive shafts, respectively, around the main rotary axis,
wherein the first to fourth main drive arms are connected to the first to fourth auxiliary drive arms, respectively, via restraint members, and rotate following rotations of the first to fourth rotary shafts, respectively, and the first to fourth mounting portions are configured to rotationally move around the main rotary axis.

2. The substrate transfer robot according to claim 1,
wherein the first main drive arm and the first auxiliary drive arm are arranged in parallel,
wherein the second main drive arm and the second auxiliary drive arm are arranged in parallel,
wherein the third main drive arm and the third auxiliary drive arm are arranged in parallel,
wherein the fourth main drive arm and the fourth auxiliary drive arm are arranged in parallel,
wherein tips of the first to fourth main drive arms and tips of the first to fourth auxiliary drive arms are rotatably fitted to the first to fourth restraint members, respectively,
wherein a first auxiliary driven arm is arranged in parallel to the first main driven arm,
wherein a second auxiliary driven arm is arranged in parallel to the second main driven arm,
wherein a third auxiliary driven arm is arranged in parallel to the third main driven arm,
wherein a fourth auxiliary driven arm is arranged in parallel to the fourth main driven arm, and
wherein base portions of the first to fourth main driven arms and base portions of the first to fourth auxiliary driven arms are rotatably fitted to the first to fourth restraint members, respectively, and tips of the first to fourth main driven arms and tips of the first to the fourth auxiliary driven arms are rotatably fitted to the first to fourth mounting portions, respectively.

3. The substrate transfer robot according to claim 1,
wherein the first to fourth main drive arms are arranged at different heights,
wherein the first to fourth main driven arms are arranged at different heights,
wherein the first to fourth mounting portions are arranged at different heights, and
wherein the first to fourth mounting portions are configured to be rotatable around the main rotary axis without colliding with each other.

4. The substrate transfer robot according to claim 1,
wherein the first auxiliary rotary axis and the third auxiliary rotary axis are arranged at positions where they are spaced apart from each other, and
wherein the second auxiliary rotary axis and the fourth auxiliary rotary axis are arranged at positions where they are spaced apart from each other.

5. The substrate transfer robot according to claim 1, wherein
the first auxiliary rotary axis and the third auxiliary rotary axis are arranged in a coincident position, and
the second auxiliary rotary axis and the fourth auxiliary rotary axis are arranged in a coincident position.

6. A vacuum processing apparatus, comprising:
a transfer chamber which can be vacuum evacuated; and
a processing chamber which is connected to the transfer chamber and in which an object to be processed is processed in a vacuum ambience,
wherein the substrate transfer robot according to claim 1 is arranged in the transfer chamber.
